(19) United States
(12) Patent Application Publication
(10) Pub. No.: US 2009/0232982 A1
(43) Pub. Date: Sep. 17, 2009

(54) POROUS FILM PRODUCTION METHOD AND APPARATUS

(75) Inventors: Koju ITO, Minami-ashigara-shi (JP); Hidekazu Yamazaki, Minami-ashigara-shi (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/404,771

(22) Filed: Mar. 16, 2009

(30) Foreign Application Priority Data
Mar. 17, 2008 (JP) 2008-067132

(51) Int. Cl. B05D 5/00; C23C 16/54

(52) U.S. Cl. 427/243; 118/724

(57) ABSTRACT

A coating liquid containing a polymer and a hydrophobic solvent is applied to a support to form a coating film. Water vapor is condensed from ambient air on a surface of the coating film. A hydrophobic solvent is evaporated until a content rate of the solvent in the coating film reaches 50 wt %. The coating film is caused to contact with liquid water. The hydrophobic solvent contained in the coating film is moved from the coating film to the water. The water and the solvent are evaporated from the coating film. Thus, a porous film having a plurality of pores is produced. It is unnecessary to adjust a surface temperature of the coating film and a dew point of the gas around the coating film precisely. It becomes possible to evaporate the hydrophobic solvent contained in the coating film rapidly.

### FIELD OF THE INVENTION

The present invention relates to a production method of a porous film having a plurality of fine pores and a production apparatus of the same.

### BACKGROUND OF THE INVENTION

In recent years, increase in integration degree, higher information density, and higher image definition have been desired more and more in fields of optical materials and electronic materials. Therefore, the film used in these fields is strongly required to have a more fine structure. As a film having the fine structure, there is a film having a honeycomb structure in which plural fine pores are formed on a surface of the film.

A method for producing a film having the honeycomb is disclosed in Japanese Patent Laid-Open Publications No. 2006-070254 and No. 2007-291367, for example. Each of these methods is a method for producing a film having a μm-scale honeycomb structure. In these methods, a polymer solution containing a predetermined polymer and a hydrophobic solvent is applied to a support to form a coating film. Air with high humidity is blown toward the coating film to cause condensation on the coating film. Water drops generated due to the condensation are evaporated from the coating film.

In the production methods disclosed in Japanese Patent Laid-Open Publications No. 2006-070254 and No. 2007-291367, the water drops generated due to the condensation make pores on the coating film. For the purpose of preventing evaporation of the water drops from the surface of the coating film, the hydrophobic solvent is evaporated from the coating film under a predetermined condition. In accordance the evaporation of the hydrophobic solvent, the coating film is hardened. Thereby, the form and size of each of the pores are not changed, and the pores are not irregularly arranged. The predetermined condition is as follows. In the method disclosed in Japanese Patent Laid-Open Publication No. 2006-070254, the surface temperature of the coating film is regulated to be equal to or less than the dew point of the gas around the coating film. In the method disclosed in Japanese Patent Laid-Open Publication No. 2007-291367, the surface temperature of the coating film is regulated to be less than the dew point of the gas around the coating film by a predetermined range. Next, under the condition that the surface temperature of the hardened coating film is higher than the dew point of the gas around the coating film by a predetermined range, the water drops are evaporated from the hardened coating film to form a μm-scale honeycomb structure on the coating film.

In the production methods disclosed in the above patent documents, it is necessary to adjust the surface temperature of the coating film and the dew point of the gas around the coating film within a predetermined range, respectively. However, the adjustment of the surface temperature of the coating film and the dew point of the gas is difficult. In particular, it is extremely difficult to adjust the dew point of the gas.

Additionally, it takes too much time for the hydrophobic solvent to evaporate from the coating film, and therefore it is impossible to shorten the time required for the production of the porous film as desired. In order to shorten the time required for the production of the porous film, it is effective to evaporate the hydrophobic solvent from the coating film rapidly by increasing the surface temperature of the coating film. However, when the surface temperature of the coating film is increased, there arises a problem in which the water droplets generated on the coating film are evaporated from the coating film prior to the evaporation of the hydrophobic solvent, and thereby resulting in a film having pores irregularly arranged with a nonuniform form and size.

### SUMMARY OF THE INVENTION

In view of the above, an object of the present invention is to provide a porous film production method and apparatus capable of evaporating a hydrophobic solvent from a coating film rapidly and producing a porous film having a desired honeycomb structure provided with pores regularly arranged with a uniform form and size.

In order to achieve the above and other objects, a porous film production method of the present invention includes the following steps. A coating liquid containing a polymer and a hydrophobic solvent is applied to a support to form a coating film. Water vapor is condensed from ambient air on a surface of the coating film to form water drops. The hydrophobic solvent is evaporated until a content rate of the hydrophobic solvent in the coating film reaches 50 wt %. The coating film on the support is caused to contact with a liquid water after the first evaporating step defined as evaporating the hydrophobic solvent until the content rate of the hydrophobic solvent in the coating film reaches 50 wt %. The water, the hydrophobic solvent, and the water drops are evaporated from the coating film to form a porous film after the water contacting step defined as causing the coating film on the support to contact with the liquid water.

According to the porous film production method of the present invention, the following condition is preferably satisfied:

Tw−Tb<20° C.

where a boiling point of the hydrophobic solvent is denoted by Tb, and a temperature of the water to be caused to contact with the coating film in the water contacting step is denoted by Tw. Preferably, the coating film on the support is caused to contact with an alcohol having a boiling point lower than that of the water between the water contacting step and the second evaporating step defined as evaporating the water, the hydrophobic solvent, and the water drops from the coating film.

A porous film production apparatus of the present invention includes a coating device for applying a coating liquid containing a polymer and a hydrophobic solvent to a support to form a coating film, a condensation device for condensing water vapor from ambient air on a surface of the coating film to form water drops, a water contacting device for causing the coating film to contact with a liquid water, a first evaporating device for evaporating the hydrophobic solvent from the coating film before being caused to contact with the water by the water contacting device, and a second evaporating device for evaporating the water droplets generated due to the condensation, the water contacting with the coating film by the water contacting device, and the hydrophobic solvent from the coating film.

According to the porous film production method of the present invention, it is possible to shorten the time require for evaporation of the hydrophobic solvent from the coating film in the process for producing a porous film having a honeycomb structure. Therefore, it is possible to shorten the time required for the production of the porous film in comparison with conventional production methods. Accordingly, it is possible to produce a porous film having desired pores regularly arranged with a uniform form and size.

### DESCRIPTION OF THE DRAWINGS

The above and other objects and advantages of the present invention will be more apparent from the following detailed description of the preferred embodiments when read in connection with the accompanied drawings, wherein like reference numerals designate like or corresponding parts throughout the several views, and wherein:

FIG. 1A is a plane view of a porous film of the present invention, FIG. 1B is a cross sectional view taken along lines b-b of FIG. 1A, FIG. 1C is a cross sectional view taken along lines c-c of FIG. 1A;

FIG. 2 is an explanation view illustrating formation of the porous film of the present invention;

FIG. 3 is a schematic view illustrating a porous film production apparatus according to a first embodiment of the present invention;

FIG. 4 is a schematic view illustrating a tank according to a second embodiment of the present invention;

FIG. 5 is a table showing conditions and evaluation results in Example 1; and

FIG. 6 is a table showing conditions and evaluation results in Example 2.

### DESCRIPTION OF THE PREFERRED EMBODIMENTS

Hereinafter, preferred embodiments of the present invention are described in detail. However, the present invention is not limited thereto.

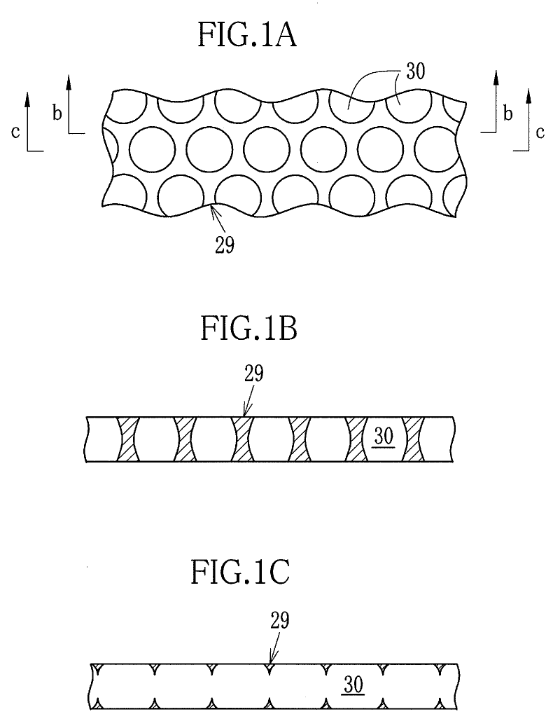

As shown in FIG. 1, a porous film 29 has a surface on which a plurality of pores 30 are densely formed. Since the plurality of pores 30 are regularly arranged with an approximately uniform form and size, the porous film 29 has a honeycomb structure.

The pores 30 adjacent to each other are aligned in the porous film 29 so as to form a communicating path along the surface of the porous film 29. In some cases, each of the pores 30 penetrates through both surfaces of the porous film 29, that is, penetrates through the porous film 29 in its thickness direction, and in other cases, the pores 30 are formed as grooves on one of the surfaces of the porous film 29 without penetrating the porous film 29.

According to this embodiment, a polymer is dissolved into a hydrophobic solvent to prepare a coating liquid 24. The coating liquid 24 is applied to a support to form a coating film. The coating film becomes the porous film 29. Accordingly, in a case where the pores 30 are formed so as to penetrate the porous film 29 in its thickness direction, when the porous film 29 on the support is viewed from a normal direction of the surface of the porous film 29, the support appears to be exposed through the pores 30.

In order to produce a long porous film, the support may be a film formed of a well-known polymer, such as a polymer film formed of polyethylene terephthalate (PET), for example. Further, in order to produce a sheet of porous film or a strip of porous film, the support may be not only a film formed of a polymer but also glass.

The coating liquid 24 preferably contains a polymer and an amphiphilic compound. The amphiphilic compound means a compound having both of a hydrophilic property and a lipophilic (hydrophobic) property, and concretely a compound having a hydrophilic group and a hydrophobic group. If the polymer has the amphiphilic property, it is not necessary to use other amphiphilic compounds with the polymer. However, if the polymer to be used for producing the porous film is regarded to have no amphiphilic property, it is preferable to use the amphiphilic compound with the polymer.

The sort of the polymer as a main component for the coating film may be chosen in accordance with intended use of the coating film. However, the number average molecular weight (Mn) of the polymer is preferably in the range of 10,000 to 10,000,000, and more preferably in the range of 50,000 to 1,000,000.

The polymer to be used with the amphiliphic compound is preferably dissolved into a nonaqueous solvent, namely, a hydrophobic solvent. For example, there are poly-ε-caprolactone, poly-3-hydroxybutyrate, agarose, poly-2-hydroxyethyl acrylate, polysulfone, and the like. In view of necessity of biodegradative properties, the cost, and the availability, poly-ε-caprolactone is particularly preferable.

Here, the hydrophobic property means low affinity for water. Concretely, when the degree of solubility of hydrophobic solvent to water is at most 5 wt %, the affinity for water is regarded as low.

As other examples of the polymer to be used with the amphiphilic compound, there are vinyl-type polymer (for example, polyethylene, polypropylene, polystyrene, polyacrylate, polymethacrylate, polyacrylamide, polymethacrylamide, polyvinyl chloride, polyvinylidene chloride, polyvinylidene fluoride, polyhexafluoropropene, polyvinyl ether, polyvinyl carbazol, polyvinyl acetate, polytetrafluoroethylene, and the like), polyesters (for example, polyethylene terephthalate, polyethylene naphthalate, polyethylene succinate, polybutylene succinate, polylactic acid, and the like), polylactone (for example, polycaprolactone and the like), polyamide or polyimide (for example, nylon, polyamic acid, and the like), polyurethane, polyurea, polycarbonate, polyaromatics, polysulfone, polyethersulfone, polysiloxane derivative, and the like. These may be used in the form of homo polymer, and otherwise used as copolymer, polymer blend, or polymer alloy, in view of solubility, optical physical properties, electric physical properties, film strength, elasticity, and the like.

As the polymer having the amphiphilic property, there is polyacrylamide, for example. As the other polymer having the amphiphilic property, there are a compound which has a main chain of polyacrylamide, a lipophilic side chain of dodecyl group, and hydrophilic side chain of carboxyl group, block copolymer of polyethylene glycol/polypropylene glycol, and the like. The lipophilic side chain is group which has nonpolar normal (linear) chain such as alkylene group, phenylene group, and the like, and preferably has a structure in which hydrophilic group such as polar group or ionic dissociative group is not divided until the end of the chain, except linking group such as ester group and amide group. The lipophilic side chain preferably has at least five methylene units if it is composed of alkylene group. The hydrophilic side chain preferably has a structure having hydrophilic part such as polar group, ionic dissociative group, or oxyethylene group on the end through a linking part such as alkylene group.

The amphiphilic compound to be mixed with the polymer is not only a monomer such as many sorts of commercially available surfactants but also an oligomer such as a dimmer and a trimer, and a polymer. When the amphiphilic compound and the polymer are mixed, water droplets are more easily formed on an exposed surface of the coating film. Further, when the dispersion condition of the polymer is controlled, the positions for forming the water droplets are more easily adjusted. When the polymer and the amphiphilic compound are mixed to be used, a weight ratio of the amphiphilic compound to the polymer is preferably in the range of 0.1% to 20%. Thus, the sizes of the formed water droplets tend to be uniform, and it becomes easy to obtain a porous film having the uniform pores. If the weight ratio of the amphiphilic compound to the polymer is less than 0.1%, the effect of adding the amphiphilic compounds is too low, and therefore the water droplets are unstably formed. Thus, the water droplets become nonuniform in size in some cases. In contrast, if the weight ratio of the amphiphilic compound to the polymer is more than 20%, the strength of the porous film becomes lower in some cases since the amphiphilic compound has low-molecular weight.

In the amphiphilic compound to be mixed with the polymer, a ratio of the number of hydrophilic group to the number of hydrophobic group is preferably in the range of 0.1/9.9 to 4.5/5.5. Thus, the more fine water droplets are formed on the coating film more densely. If the ratio of the number of hydrophilic group to the number of hydrophobic group doesn't satisfy the above range, the size of the pores becomes various, and concretely, a variation coefficient (unit: %) of the porous diameter that is determined as {(standard deviation of porous diameter)/(average of porous diameter)}×100 becomes 10% or more in some cases. Further, otherwise, it sometimes becomes hard to arrange the pores regularly.

Preferably, at least two sorts of the amphiphilic compounds different form each other are used. Thus, it becomes possible to control the position and the size of the water droplets. In addition, preferably, at least two sorts of the polymers are used, such that the same effects as described above can be achieved.

The sort of the solvent to be used in the coating liquid 24 is not restricted, so far as it is hydrophobic and the polymer can be dissolved into it. For example, there are chloroform, dichloromethane, tetrachloromethane, cyclohexane, methyl acetate, and the like. The solvent may contain at least two different sorts of the solvent components, and the mixture ratio thereof may be changed adequately.

Preferably, in the coating liquid 24, the content of the polymer is in the range of 0.02 pts.wt. to 20 pts.wt., if the content of the solvent is determined as 100 pts.wt.

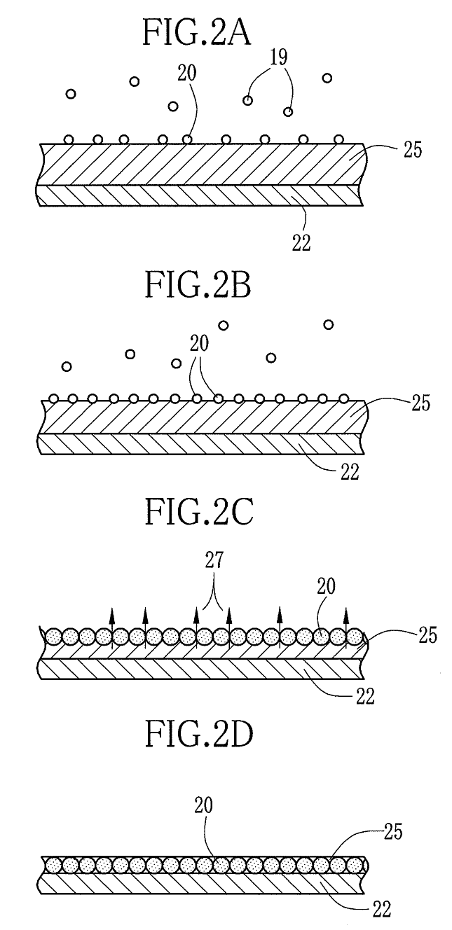

A porous film production process includes a coating process, a condensation process, and a drying process. In the coating process, the coating liquid 24 is applied to the support 22 to form the coating film 25. In the condensation process, water vapor is condensed from ambient air on a surface of the coating film 25 to generate water droplets thereon. In the drying process, the coating film 25 is dried to form a porous film 29 having the plurality of pores 30. As shown in FIGS. 2A and 2B, in the condensation process after the coating process, moisture 19 is condensed from ambient air on a surface of the coating film 25 on the support 22 to form water drops 20. Further, as shown in FIG. 2C, in the drying process, solvents 27 are evaporated from the coating film 25. In accordance with the evaporation of the solvents 27, as shown in FIG. 2D, the water droplets 20 enter the coating film 25. The drying process includes a first evaporation process, a water contacting process, and a second evaporation process. The first evaporation process is performed for the purpose of evaporating the solvents 27 from the coating film 25 until the content rate of the solvents 27 in the coating film 25 reaches a predetermined level. The water contacting process is performed for the purpose of causing the coating film 25, which has been subjected to the first evaporation process, to contact with water. The second evaporation process is performed for the purpose of evaporating the water and the solvents 27 from the coating film 25 after the water contacting process. The first evaporation process is performed such that the water droplets 20 enter the coating film 25 so as to have a honeycomb structure. Both of the water droplets 20 and the water adhered to the coating film 25 during the water contacting process are evaporated in the second evaporation process. Upon evaporation of the water and the solvents 27, areas occupied by the water droplets 20 become the pores 30. Thereby, the honeycomb structure can be obtained.

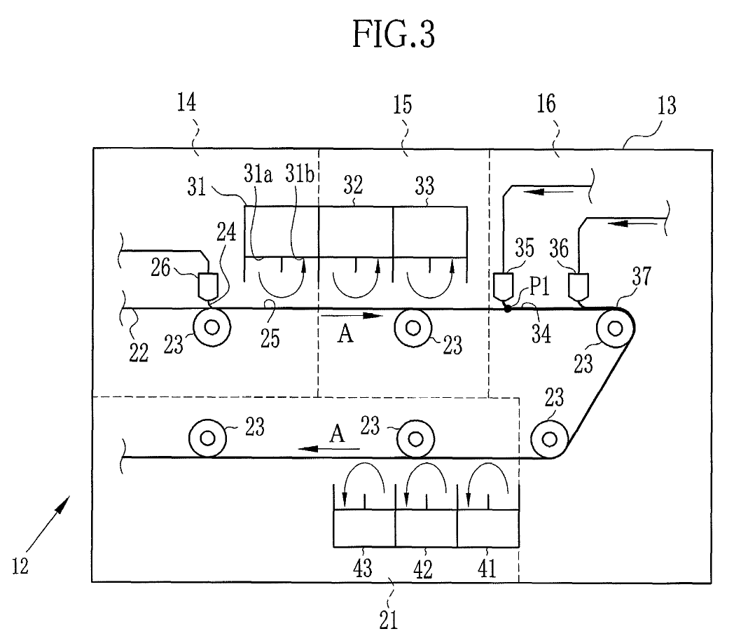

As shown in FIG. 3, according to a first embodiment, a porous film production apparatus 12 includes a coating chamber 13. The coating chamber 13 is partitioned into a first area 14 for performing the coating process and the condensation process, a second area 15 for performing the first evaporation process, a third area 16 for performing the water contacting process, and a fourth area 21 for performing the second evaporation process. That is, the drying process is performed from the second area 15 to the fourth area 21. Although the coating chamber 13 is an integrated chamber partitioned into the above-described areas in this embodiment, each of the areas may be formed of an independent chamber so as to constitute the porous film production apparatus by plural chambers. Note that an arrow A in FIG. 3 shows a direction in which the support 22 moves.

A plurality of rollers 23 are disposed in the first area 14, the second area 15, the third area 16, and the fourth area 21. A peripheral surface of each of the rollers 23 supports the support 22. The rollers 23 include drive rollers. The drive rollers rotate to convey the support 22. The first area 14 includes a discharge die 26 for discharging the coating liquid 24 onto the support 22, and an air feeding/sucking unit 31 disposed above a conveying path for the support 22. The second area 15 includes air feeding/sucking units 32 and 33. The third area 16 includes a water discharge die 35 for discharging water 34 onto the coating film 25, and an alcohol discharge die 36 for discharging alcohol 37 onto the coating film 25. The coating film 25 starts to contact with the water 34 at a contact start position P1. The fourth area 21 includes air feeding/sucking units 41 to 43. Each of the air feeding/sucking units 41 to 43 may be two or more and arranged in line in a moving direction of the support 22. The solvent vapor 27 in the coating chamber 13 is recovered by a not-shown recovery device, and then refined by a not-shown refining device provided outside the coating chamber 13 to be reused. Note that the structures of air feeding/sucking units 31 to 33 and 41 to 43 are approximately identical to each other.

In the first area 14, the coating liquid 24 is discharged through the discharge die 26 onto the moving long support 22 to be the coating film 25. The coating liquid 24 is preferably applied to the support 22 such that the thickness of the coating film 25 before being dried is constant within the range of 0.01 mm to 1 mm. Even when the thickness of the coating film 25 is within the range of 0.01 mm to 1 mm, variation in thickness of the coating film 25 makes it impossible to form the water droplets having a uniform diameter in some cases. When the thickness of the coating film 25 is less than 0.01 mm, the coating film 25 may have a problem such as thickness unevenness and pores irregularly arranged with nonuniform size and form in some cases. In contrast, when the thickness of the coating film 25 exceeds 1 mm, it takes too much time to dry the coating film 25, and therefore the production efficiency may be decreased in some cases.

The air feeding/sucking unit 31 has an outlet 31a for feeding wet air at the vicinity of the coating film 25 and an inlet 31b for sucking gas around the coating film 25. Further, the air feeding/sucking unit 31 is provided with a blowing controller (not shown) for independently controlling a temperature, a dew point, a humidity, and a wind speed of the air to be fed, and a suction force for sucking the air. The outlet 31a has a filter for keeping a dust level, namely a cleaning level of the wet air. A plurality of the air feeding/sucking unit 31 may be arranged in the moving direction of the support 22.

The dew point of the air fed from the outlet 31a is denoted by TD, and a surface temperature of the coating film 25 is denoted by TS. A value obtained by subtracting TS from TD is denoted by AT. In this case, at least one of the values TD and TS is preferably controlled, such that a following condition is satisfied: 3° C.≦ΔT≦30° C. The surface temperature TS of the coating film 25 can be measured by, for example, a non-contact thermometer (such as an infrared thermometer commercially available) that is disposed near a conveying path of the coating film 25. When the value AT is less than 3° C., the water droplets due to the condensation are hardly generated. In contrast, when the value ΔT is more than 30° C., the water droplets are generated suddenly. In this case, the water droplets become nonuniform in size, and otherwise, the water droplets, which should be arranged in two dimensional arrangement (in a matrix manner), are arranged in three dimensional arrangement in which one of the water droplets overlaps on the other one.

In the first area 14, the surface temperature TS of the coating film 25 is controlled by the support 22 contacting with the rollers 23 and a temperature controlling plate (not shown) disposed so as to face the support 22. However, the surface temperature TS may be controlled by one of the support 22 and the temperature controlling plate. Furthermore, the dew point TD is controlled by adjusting the humidification conditions of the wet air fed from the outlet 31a of the air feeding/sucking unit 31.

In the second area 15, the air feeding/sucking units 32 and 33 are arranged in this order from the upstream side in the conveying path of the coating film 25. The air feeding/sucking unit 32 is disposed closely next to and downstream from the air feeding/sucking unit 31 of the first area 14.

In the second area 15, at least one of the values TS and TD is preferably controlled, such that a following condition is satisfied: 0° C.<ΔT≦10° C. The surface temperature TS of the coating film 25 is controlled mainly by a temperature controlling plate (not shown) disposed at the vicinity of the coating film 25. The temperature controlling plate has a structure basically equivalent to that disposed in the first area 14, and can change the surface temperature TS along the moving direction of the support 22. Furthermore, the dew point TD is controlled by adjusting the humidification conditions of the wet air fed from the outlet of the air feeding/sucking unit.

It is preferable that the coating film 25 is caused to contact with the water 34 in a liquid state in the third area 16 after the water droplets 20 enter the coating film 25 so as to have a honeycomb structure as shown in FIG. 2D. Namely, the timing for causing the coating film 25 to contact with the water 34 is preferably determined with reference to the depth of the water droplets 20 entering the coating film 25. However, it may be difficult to measure the depth of the water droplets 20 entering the coating film 25 promptly in some cases. In this case, the timing for causing the coating film 25 to contact with the water 34 in the third area 16 is preferably determined based on the content rate of the solvent in the coating film 25. This is because there is a certain relation between the content rate of the solvent in the coating film 25 and the depth of the water droplets 20 entering the coating film 25 in a case where the above process is performed in the first area 14 and the second area 15.

The solvents 27 are evaporated in the second area 15 such that the content rate of the solvent in the coating film 25 reaches 50 wt % at the time when the support 22 reaches the contact start position P1. When the content rate of the solvent in the coating film 25 reaches 50 wt %, the depth of thewater droplets 20 entering the coating film 25 is enough to have the honeycomb structure. When the content rate of the solvent in the coating film 25 reaches 50 wt % at the contact start position P1, the content rate of the solvent in the coating film 25 is at most 50 wt % at the contact start position P1. Although the content rate of the solvent in the coating film 25 at the contact start position P1 may be less than 50 wt %, for the purpose of increasing the production efficiency, the water contacting process is preferably performed immediately after the content rate of the solvent in the coating film 25 reaches 50 wt %. Further, if the water contacting process is performed at the timing when the content rate of the solvent in the coating film 25 at the contact start position P1 is more than 50 wt %, namely, at the timing when the content rate of the solvent in the coating film 25 is more than 50 wt %, the porous film 29 can be produced in some cases, however, in other cases, the water droplets 20 enter the coating film 25 insufficiently such that the pores 30 become shallow grooves on the coating film 25 in accordance with the sorts of the polymer and the solvent. Accordingly, it is preferable that the content rate of the solvent in the coating film 25 at the contact start position P1 is at most 50 wt % for the purpose of achieving the effect surely. For example, it is preferable that the coating film 25 is dried in the second area 15 such that the content rate of the solvent in the coating film 25 reaches 50 wt % at the downstream end of the second area 15. Note that the content rate of the solvent is obtained by 100×X/(X+Y) wherein the weight of the solvent 27 contained in the coating film 25 is denoted by X and the weight of the polymer contained in the coating film 25 is denoted by Y.

Whether the content rate of the solvent in the coating film 25 reaches 50 wt % or not can be judged by the thickness of the coating film 25. For example, a non-contact thickness measuring device (not-shown) is disposed at the vicinity of the conveying path of the support 22. Thus, whether the content rate of the solvent in the coating film 25 reaches 50 wt % or not can be judged by correlation between the target thickness of the porous film 29 and the thickness of the coating film 25 measured by the non-contact thickness measuring device.

Whether the depth of the water droplets 20 entering the coating film 25 is enough to have the honeycomb structure also can be judged by eyes. In this case, refraction of light on the water droplets 20 generated due to the condensation is utilized. While observing the coating film 25 in the second area 15 over time, it can be observed that the coating film 25 seems rainbow at first and then the rainbow disappears. The timing when the rainbow disappears approximately corresponds to the timing when the water droplets 20 enter the coating film 25 enough to have the honeycomb structure. Accordingly, a mode in which the solvents 27 are evaporated in the second area 15 until the content rate of the solvent reaches 50 wt % may be substituted with a mode in which the solvents 27 are evaporated in the second area 15 until the rainbow disappears from the coating film 25. The method utilizing the refraction of light as described above can be easily performed by applying light toward the coating film 25.

In the third area 16, the liquid water 34 is discharged through the water discharge die 35 onto the coating film 25 fed from the second area 15 to cause the coating film 25 to contact with the water 34. In the conventional manner, in a first evaporation process performed in the second area 15, the hydrophobic solvent in the coating film 25 does not sufficiently evaporate in accordance with the sort of the polymer and the hydrophobic solvent. Thus, a porous film having a desired honeycomb structure can not be obtained. However, according to this embodiment, the coating film 25 is caused to contact with the water 34 such that the evaporation of the water droplets 20 filling the pores 30 in the coating film 25 can be prevented by the water 34. Further, since the hydrophobic solvent moves to the water 34 and the water droplets 20 in the coating film 25, it is possible to efficiently remove the hydrophobic solvent from the coating film 25 in conjunction with the process performed in the fourth area 21.

It is preferable that the temperature of the water 34 is set so as not to cause bumping of the hydrophobic solvent in the coating film 25 contacting with the water 34. In order to prevent the bumping of the hydrophobic solvent, the temperature of the water 34 should not be 20° C. higher than that of the hydrophobic solvent. Namely, when the boiling point of the hydrophobic solvent is denoted by Tb, and the temperature of the water 34 to contact with the coating film 25 is denoted by Tw, the value obtained by subtracting Tb from Tw is preferably less than 20° C. Accordingly, the value obtained by subtracting Tb from Tw preferably satisfies the following condition: Tw−Tb<20° C. Note that, when the Tw is not larger than Tb, it is possible to prevent the bumping of the hydrophobic solvent approximately completely. In contrast, in order to increase the drying efficiency of the coating film 25, Tw should not be 60° C. lower than Tb. Namely, the value obtained by subtracting Tb from Tw is preferably larger than −60° C., and more preferably satisfies the following condition: −60° C.<Tw−Tb. Accordingly, it is preferable that the selection of the hydrophobic solvent and the setting of the temperature of the water 34 are performed such that the following condition is satisfied: −60° C.<Tw−Tb<20° C. However, −60° C. as the lower limit may change in accordance with the sort of the solvent, the target level of the production efficiency, and the like. In a case where the value obtained by subtracting Tb from Tw exceeds 20° C., the hydrophobic solvent contained in the coating film 25 is heated rapidly by the water 34 contacting with the coating film 25, and the bumping of the hydrophobic solvent may occur in some cases. In contrast, in a case where the value obtained by subtracting Tb from Tw is −60° C. or less, the efficiency of drying the coating film 25 by evaporating the water 34 and the hydrophobic solvent from the coating film 25 is decreased.

A plurality of the water discharge dies 35 may be arranged along the conveying path of the support 22 such that the coating film 25 is caused to contact with the water 34 many times. Thereby, it becomes possible to remove hydrophobic solvents from the coating film 25 more efficiently. In this case, the temperature of the water discharged from the water discharge die in the downstream side is more preferably higher than that of the water discharged from the water discharge die in the upstream side. Higher the temperature of the water is, the faster the hydrophobic solvent moves to the water.

Although the coating film 25 is caused to contact with the water 34 in this embodiment, alcohol or hydrophilic solvent which does not dissolve the polymer may be used instead of the water 34.

In the third area 16, after the coating film 25 is caused to contact with the water 34, the alcohol 37 is preferably discharged through the alcohol discharge die 36 onto the coating film 25 to cause the coating film 25 to contact with the alcohol 37 in an alcohol contacting process. The alcohol 37 preferably has the boiling point lower than that of the water 34. Since the alcohol having the boiling point lower than that of the water has strong affinity for the water, the evaporation of the water is accelerated. Additionally, the alcohol also has affinity for the hydrophobic solvent, and therefore upon the evaporation of the water, the alcohol exerts the effect of evaporating the hydrophobic solvent. Accordingly, due to the contact with the alcohol, the efficiency of drying the coating film 25 in the fourth area 21 can be further increased. Further, when the temperature of the alcohol is denoted by Ta and the temperature of the water is denoted by Tw, it is preferable that the following condition is satisfied: Ta>Tw. This is because the alcohol 37 easily evaporates, and in accordance with the evaporation of the alcohol 37, the water also easily evaporates.

The alcohol contacting process may be performed between the water contacting process and a second evaporation process, or/and during the second evaporation process. The alcohol 37 is preferably ethanol, isopropyl alcohol, or the like to dry the coating film 25 efficiently and rapidly.

Instead of the alcohol discharge die 36, a liquid bath containing alcohol maybe disposed. The coating film 25 is guided to the alcohol in the liquid bath, and caused to contact with the alcohol. In this case, there are disposed rollers 23 for contacting and supporting the support 22 in the liquid bath. In order to soak the coating film 25 in the alcohol without fail, it is preferable that the level of the lower end of at least one of the rollers 23 is below the liquid surface of the alcohol.

In the fourth area 21, dry air is fed through the air feeding/sucking units 41 to 43 toward the coating film 25, and thereby the water droplets 20 contained in the coating film 25, the water adhered to the surface of the coating film 25 by the water contacting process, and the hydrophobic solvent are evaporated from the coating film 25 to dry the coating film 25. Note that, in a case where the alcohol contacting process is performed in the third area 16, the alcohol 37 is also evaporated from the coating film 25 in the fourth area 21.

The porous film production apparatus 12 further includes a feeding means (not shown) for feeding the roll of long support to the first area 14, and a winding means (not shown) for winding the porous film 29.

According to the above production method, it is possible to shorten the time required for the evaporation of the hydrophobic solvents in comparison with the conventional method.

For the purpose of applying the coating liquid 24, there are two methods. In the first method, the coating liquid is discharged onto a support disposed stationary and spread over the support. In the second method, the coating liquid is discharged through the discharge die onto a moving support. Both of them are applicable to the present invention. The first method is generally suitable for high-mix low-volume production. The second method is generally suitable for mass production. Note that, in the second method, if the coating liquid is continuously discharged, a long porous film can be produced, and if the coating liquid is intermittently discharged at a predetermined interval, a plurality of the porous films having a predetermined length can be produced one by one continuously.

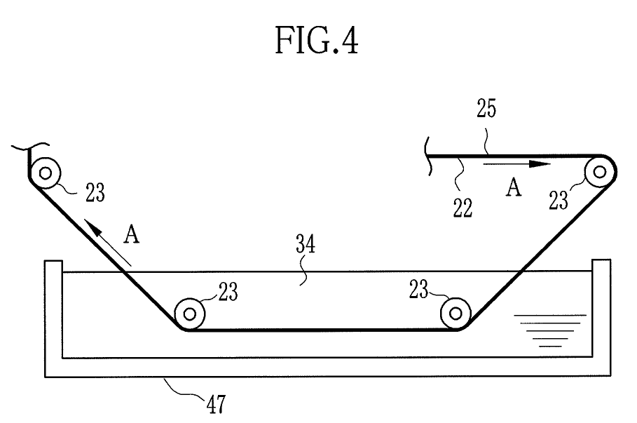

Next, by referring to FIG. 4, a second embodiment is explained. The components identical to those in FIG. 3 have the same reference numerals in FIG. 4. Instead of the water discharge die 35 (see FIG. 3) used in the first embodiment, a tank 47 is used in the second embodiment. In other words, as the water contacting process, instead of applying the water 34 to the coating film 25, the coating film 25 is soaked in the water 34 contained in the tank 47. FIG. 4 schematically shows only the conveying path of the coating film 25 contacting with the water 34 in the third area 16 (see FIG. 3). The process performed in the upstream side from the third area 16 and the process performed from the alcohol discharge die 36 to the downstream side in the third area 16 are the same as those in the first embodiment, and therefore the explanation and drawing thereof will be omitted.

A tank 47 is disposed in the third area 16. The rollers 23 for contacting and supporting the support 22 are disposed in the tank 47. The level of the lower end of at least one of the rollers 23 is below the liquid surface of the water 34 such that the coating film 25 is soaked together with the support 22 in the water 34. After passing through the second area 15 (see FIG. 3), the coating film 25 is guided to the water 34 in the tank 47 in accordance with the movement of the support 22, and then caused to contact with water 34. Instead of using the water discharge die 35 in the first embodiment, the tank 47 is used in the second embodiment, and therefore an amount of the water 34 contacting with coating film 25 is increased and the time for causing the coating film 25 to contact with the water 34 is also increased in comparison with the first embodiment. Accordingly, even if the hydrophobic solvents are diffused toward the water 34, the concentration of the hydrophobic solvents in the water 34 does not easily increased, and the difference between the concentration of the hydrophobic solvents at the vicinity of the coating film 25 and the concentration of the hydrophobic solvents in the water 34 can be easily maintained at a constant level. Thereby, the hydrophobic solvents more easily move to the water 34 due to the difference in concentration, and therefore the efficiency of drying the coating film 25 can be increased.

A plurality of the tanks 47 may be arranged in series along the moving direction of the support 22 to perform the water contacting process many times. Thus, the hydrophobic solvents can be more surely removed from the coating film 25. Also in this case, the temperature of the water contained in the tank in the downstream side is preferably higher than that of the water contained in the tank in the upstream side. Thereby, it is possible to achieve more efficient drying of the coating film 25 while preventing bumping of the hydrophobic solvent.

Additionally, the coating film 25 is preferably caused to contact with alcohol 37 (see FIG. 3) after passing through the tank 47 as in the case of the first embodiment.

According the film production method of the present invention, the coating film is caused to contact with the water in the process for producing the porous film having the honeycomb structure, and therefore it is possible to shorten the time required for evaporation of the hydrophobic solvents in comparison with the conventional method. Accordingly, it is possible to produce the porous film having pores regularly arranged with a uniform form and size in a short period of time.

### EXAMPLE 1

### [Experiments 1 to 11]

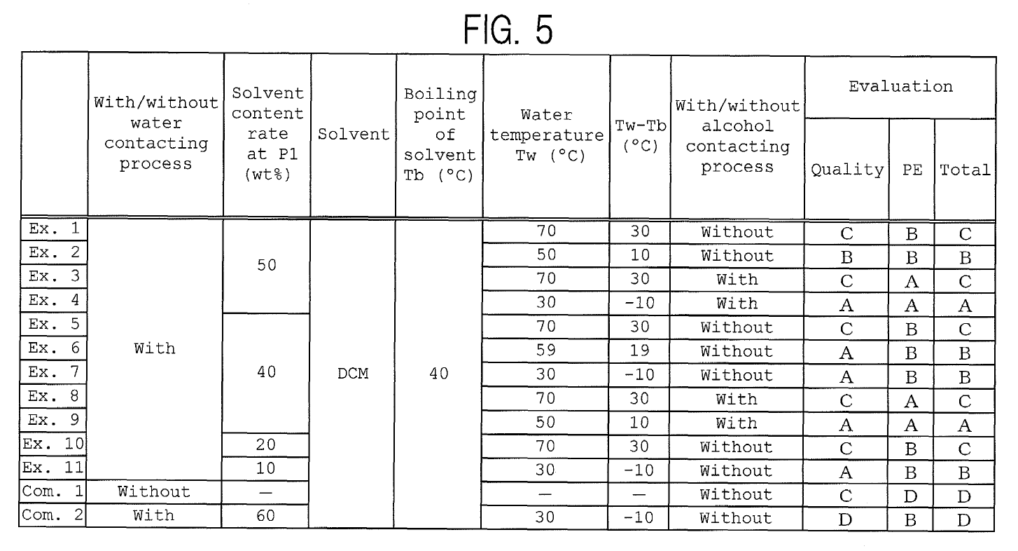

The porous film 29 was produced by the porous film production apparatus 12 under a condition different from each other in each of Experiments 1 to 11. Each of the conditions is shown in a table in FIG. 5. The support 22 was a film formed of PET. The solvent contained in the coating liquid 24 was dichloromethane having the boiling point Tb of 40° C., and the content rate of the solvent in the coating liquid 24 was 98.9 wt %. The composition of the coating liquid 24 is as follows.

| | |
|---|---|
| Polybutadiene | 1 pts. wt. |
| Dichloromethane (DCM) | 98.9 pts. wt. |
| Amphiphilic polyacrylamide | 0.1 pts. wt. |

The coating film 25 was dried until the content rate of the solvent reaches a predetermined level in the second area 15. Then, in the third area 16, the water contacting process was performed such that the coating film 25 was caused to contact with the water 34 discharged through the water discharge die 35. According to each Experiment, the content rate of solvent (unit: wt %) at the contact start position P1 is shown in a column “Solvent content rate at P1” in the table in FIG. 5, and the temperature Tw of the water 34 (unit: ° C.) is shown in a column “Water temperature Tw” in the table in FIG. 5, respectively.

In some Experiments, the alcohol contacting process was performed after the water contacting process in the third area 16. Whether the alcohol contacting process was performed or not is shown in a column “With/without alcohol contacting process” in the table in FIG. 5. The alcohol 37 was continuously applied to the coating film 25 through the alcohol discharge die 36 to cause the coating film 25 to contact with the alcohol 37. The alcohol 37 used in this example was ethanol having the boiling point of 78° C., and the temperature of the alcohol 37 was 30° C.

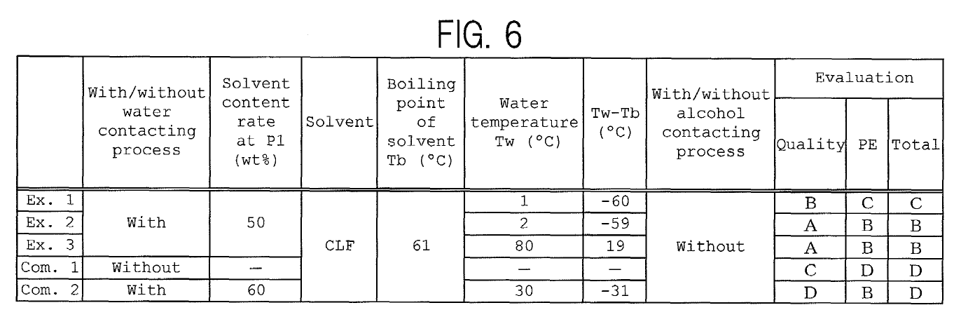

Next, the coating film 25 was dried in the fourth area 21 to obtain the porous film 29. The quality of the porous film 29 obtained in each Experiment was evaluated. The production efficiency of the porous film 29 in each Experiment was also evaluated. Further, total evaluation was performed based on the above evaluation results. The quality of the porous film 29 was evaluated in accordance with whether or not irregularity appeared and degree of the irregularity, the uniformity of the forms and sizes of the pores, and regularity of the arrangement of the pores. The production efficiency was evaluated in accordance with the time required for drying the applied coating liquid 24 enough to be wound, that is, the length of production time of the porous film 29. Note that the production efficiency is denoted by PE in FIGS. 5 and 6. The procedures and criteria for each evaluation are concretely explained below.

With regard to the evaluation of quality, whether or not irregularity appeared and degree of the irregularity were checked by eyes. With regard to the uniformity of the forms and sizes of the pores, and regularity of the arrangement of the pores, the porous diameter was measured by a laser microscope, and the measured porous diameter was evaluated. The criteria for evaluation of the quality were as follows. Note that the variation coefficient (unit: %) of the porous diameter was determined as {(standard deviation of porous diameter)/(average of porous diameter)}×100.
A: There was no irregularity, uniformity was kept, and the variation coefficient was at most 5%.
B: There was no irregularity, uniformity was kept, and the variation coefficient was more than 5% and at most 10%.
C: There was little irregularity, uniformity was almost kept, and the variation coefficient was more than 10% and at most 15%.
D: There was irregularity, and the variation coefficient was more than 15%.

The criteria for evaluation of the production efficiency were as follows.
A: less than 20 minutes.
B: not less than 20 minutes and not more than 40 minutes.
C: not less than 40 minutes and not more than 60 minutes.
D: more than 60 minutes.

Total evaluation was based on the following criteria. The total evaluation results are shown in a column “Total” in the table in FIG. 5.
A: Both quality and production efficiency were evaluated as A.
B: Both quality and production efficiency were evaluated as A or B (except the case in which both of them were evaluated as A).
C: Both quality and production efficiency were evaluated as A, B, or C (except the case in which both of them were evaluated as A or B).
D: Any one of quality and production efficiency was evaluated as D.

### COMPARATIVE EXAMPLE 1

The porous film was produced without performing the water contacting process and the alcohol contacting process. Concretely, the water discharge die 35 and the alcohol discharge die 36 in the third area 16 were substituted with air feeding/sucking units similar to the air feeding/sucking units 41 to 43 in the fourth area 21, and the coating film 25 guided from the second area 15 was dried. Other conditions were the same as those in Experiment 1. The obtained porous film was evaluated in the similar manner as those in Experiments 1 to 11.

### COMPARATIVE EXAMPLE 2

The alcohol contacting process was not performed, and the water temperature Tw during the water contacting process was set to a value shown in the table in FIG. 5 such that the content rate of the solvent at P1 became a level shown in the table in FIG. 5. Other conditions were the same as those in Experiment 7. The obtained porous film was evaluated in the similar manner as those in Experiments 1 to 11.

### EXAMPLE 2

### [Experiments 1 to 3]

The coating liquid 24 in Example 1 was substituted with the coating liquid 24 having the following composition. The solvent contained in the coating liquid 24 was chloroform having the boiling point Tb of 61° C., and content rate of solvent in the coating liquid 24 was 98.9 wt %.

| | |
|---|---|
| Polybutadiene | 1 pts. wt. |
| Chloroform (CLF) | 98.9 pts. wt. |
| Amphiphilic polyacrylamide | 0.1 pts. wt. |

The porous film 29 was produced using the coating liquid 24 described above under a condition different from each other in each of Experiments 1 to 3. The obtained porous film 29 was evaluated in the similar manner as those in Example 1. The conditions and the evaluation results are shown in a table in FIG. 6.

### COMPARATIVE EXAMPLE 1

The porous film was produced without performing the water contacting process and the alcohol contacting process. Concretely, the water discharge die 35 and the alcohol discharge die 36 in the third area 16 were substituted with air feeding/sucking units similar to the air feeding/sucking units 41 to 43 in the fourth area 21, and the coating film 25 guided from the second area 15 was dried. Other conditions were the same as those in Experiment 1. The obtained porous film was evaluated in the similar manner as those in Experiments 1 to 3.

### COMPARATIVE EXAMPLE 2

The alcohol contacting process was not performed, and the water temperature Tw during the water contacting process was set to a value shown in the table in FIG. 6 such that the content rate of the solvent at P1 became a level shown in the table in FIG. 6. Other conditions were the same as those in Experiment 1. The obtained porous film was evaluated in the similar manner as those in Experiments 1 to 3.

Various changes and modifications are possible in the present invention and may be understood to be within the present invention.

What is claimed is:

1. A porous film production method comprising the steps of:
applying a coating liquid containing a polymer and a hydrophobic solvent to a support to form a coating film;
condensing water vapor from ambient air on a surface of said coating film to form water drops;
evaporating said hydrophobic solvent until a content rate of said hydrophobic solvent in said coating film reaches 50 wt %;
causing said coating film on said support to contact with a liquid water after the first evaporating step defined as evaporating said hydrophobic solvent until the content rate of said hydrophobic solvent in said coating film reaches 50 wt %; and
evaporating said water, said hydrophobic solvent, and said water drops from said coating film to form a porous film after the water contacting step defined as causing said coating film on said support to contact with said liquid water.

2. A porous film production method as defined in claim 1, wherein the following condition is satisfied:
Tw−Tb<20° C.
where a boiling point of said hydrophobic solvent is denoted by Tb, and a temperature of said water to be caused to contact with said coating film in the water contacting step is denoted by Tw.

3. A porous film production method as defined in claim 2, wherein said coating film on said support is caused to contact with an alcohol having a boiling point lower than that of said water between the water contacting step and the second evaporating step defined as evaporating said water, said hydrophobic solvent, and said water drops from said coating film.

4. A porous film production apparatus comprising:
a coating device for applying a coating liquid containing a polymer and a hydrophobic solvent to a support to form a coating film;
a condensation device for condensing water vapor from ambient air on a surface of said coating film to form water drops;
a water contacting device for causing said coating film to contact with a liquid water;
a first evaporating device for evaporating said hydrophobic solvent from said coating film before being caused to contact with said water by said water contacting device; and
a second evaporating device for evaporating said water droplets generated due to the condensation, said water contacting with said coating film by said water contacting device, and said hydrophobic solvent from said coating film.
